(19) United States
(12) Patent Application Publication
(10) Pub. No.: US 2005/0139878 A1
(43) Pub. Date: Jun. 30, 2005

(54) CMOS image sensor and method for fabricating the same

(75) Inventors: Chang Hun Han, Icheon (KR); Bum Sik Kim, Suwon (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/022,886

(22) Filed: Dec. 28, 2004

(30) Foreign Application Priority Data
Dec. 31, 2003 (KR) P 2003-0101552

(51) Int. Cl. H01L 31/062

(52) U.S. Cl. 257/292

(57) ABSTRACT

A CMOS image sensor and a method for fabricating the same are disclosed, in which a defect caused by impurity ion implantation at the boundary between an active region below a gate electrode of a transistor constituting a CMOS image sensor and a device isolation film can be minimized. The CMOS image sensor includes a first conductive type semiconductor substrate having a plurality of transistors, an active region overlapping each gate electrode of the transistors, a device isolation film adjacent to the active region, and a first conductive type heavily doped impurity ion region formed between the active region and the device isolation film.

This application claims the benefit of the Korean Application No. P2003-101552 filed on Dec. 31, 2003, which is hereby incorporated by reference.

### BACKGROUND OF THE INVENTION

1. Field of the Invention

The present invention relates to a CMOS image sensor and a method for fabricating the same, and more particularly, to a CMOS image sensor and a method for fabricating the same in which a defect caused by impurity ion implantation at the boundary between an active region below a gate electrode of a transistor constituting a CMOS image sensor and a device isolation film can be minimized.

2. Discussion of the Related Art

Generally, an image sensor means a semiconductor device converting optical images into electrical signals. The image sensor is divided into a charge coupled device (CCD) and a complementary MOS (CMOS) image sensor. The CCD transfers and stores charge carrier to and in a capacitor in a state that respective MOS capacitors lie adjacent to each other. The CMOS image sensor employs a switching mode that provides MOS transistors by the number of pixels using CMOS technology based on peripheral circuits such as a control circuit and signal processing circuit and that detects output signals of the MOS transistors.

The CCD has several drawbacks. That is, the CCD requires much power consumption and its driving mode is complicated. Also, since a lot of mask process steps are required, a signal processing circuit cannot be realized within a CCD chip.

To solve such drawbacks, studies of a CMOS image sensor based on sub-micron CMOS technology have been progressed recently. In the CMOS image sensor, images are realized by forming a photodiode and a MOS transistor within a unit pixel and detecting signals in a switching mode. In this case, less power consumption is required because the CMOS technology is used. Also, since twenty masks are required, the process steps are simpler than those of the CCD, which require thirty to forty masks. Thus, a signal processing circuit can be integrated within a single chip. This enables a small sized product and various applications of the product.

A related art CMOS image sensor will now be described with reference to FIG. 1 and FIG. 2. FIG. 1 and FIG. 2 are a circuit diagram and a layout illustrating a unit pixel structure of a related art CMOS image sensor. Although three or more transistors constituting a CMOS image sensor may be used, for convenience, a CMOS image sensor based on three transistors will be described.

As shown in FIG. 1 and FIG. 2, a unit pixel 100 of the CMOS image sensor includes a photodiode 110 and three NMOS transistors. The photodiode 110 serves as a sensor. Of the three transistors, a reset transistor Rx 120 transfers optical charges generated in the photodiode 110 and discharges the charges to detect signals. Another driver transistor Dx 130 serves as a source follower. Other select transistor Sx 140 is for switching and addressing.

Meanwhile, in the image sensor of the unit pixel, the photodiode 110 serves as a source of the reset transistor Rx 120 to facilitate charge transfer. To this end, the process steps of fabricating an image sensor of a unit pixel include the step of lightly or heavily implanting impurity ions into a region including some of the photodiode as shown in FIG. 2.

The process steps of fabricating an image sensor of a unit pixel corresponding to the section taken along line A-A′ of FIG. 2 will be described with reference to FIG. 3A to FIG. 3C. For reference, a solid line of FIG. 2 denotes an active region 160.

As shown in FIG. 3A, a gate insulating film 122 and a gate electrode 123 are sequentially formed on a P type semiconductor substrate P⁺⁺-sub 101 in which a device isolation film 121 is formed by a shallow trench isolation (STI) process. In this case, a P type epitaxial layer P⁻-epi may previously be formed in the P type semiconductor substrate 101. Subsequently, a photoresist film is deposited on the entire surface of the semiconductor substrate 101. A photoresist pattern 124 is then formed on a drain region at one side of the gate electrode 123 by a photolithography process to define a lightly doped impurity ion region for a lightly doped drain (LDD) structure. At this time, the gate electrode is not exposed by the photoresist pattern 124.

In this state, lightly doped impurity ions, for example, N type impurity ions are implanted into the entire surface of the semiconductor substrate to form a lightly doped impurity ion region LDD n− for the LDD structure in the semiconductor substrate 101.

Subsequently, as shown in FIG. 3B, another photoresist pattern 125 is formed to form a lightly doped impurity ion region n− for a photodiode using the photoresist pattern 125 as an ion implantation mask. At this time, the lightly doped impurity ion region LDD n− is not exposed by the photoresist pattern 125.

Afterwards, as shown in FIG. 3C, a spacer 126 is formed at sidewalls of the gate electrode 123, and a P type impurity ion region P⁰ is formed on the N type impurity ion region n−. Thus, the process steps of forming a photodiode are completed. In a state that the photodiode is completed, heavily doped impurity ions are selectively implanted into the drain region of the gate electrode 123 to form a heavily doped impurity ion region n+. Finally, the process steps corresponding to the section taken along line A-A′ of FIG. 2 are completed.

In the method for fabricating the related art CMOS image sensor, impurity ions are implanted into the active region corresponding to the solid line of FIG. 2 several times to form a photodiode and a diffusion region. In the step of implanting impurity ions several times referring to the section taken along line B-B′ of FIG. 2, an ion implantation mask 127 for impurity ion implantation is formed on the semiconductor substrate including the gate electrode in a state that the gate insulating film and the gate electrode are formed on the device isolation film and the active region of the semiconductor substrate in which the active region is defined by the device isolation film as shown in FIG. 4. The ion implantation mask exposes the active region. The step of implanting impurity ions includes the lightly doped impurity ion implantation for the LDD structure (see FIG. 3A), the heavily doped impurity ion implantation for the source and drain regions (see FIG. 3C), and the impurity ion implantation for the photodiode (see FIG. 3B).

As described above, the impurity ions are implanted into the active region after the active region is defined. At this time, a defect occurs at the boundary A between the active region and the device isolation film adjacent to the active region due to ion implantation. Such a defect due to ion implantation occurs in the gate electrodes of all the transistors constituting the unit pixel of the CMOS image sensor. Also, the defect causes electron-hole carrier and provides a recombination area of the electron-hole, thereby increasing leakage current.

### SUMMARY OF THE INVENTION

Accordingly, the present invention is directed to a CMOS image sensor and a method for fabricating the same that substantially obviates one or more problems due to limitations and disadvantages of the related art.

An object of the present invention is to provide a CMOS image sensor and a method for fabricating the same in which a defect caused by impurity ion implantation at the boundary between an active region below a gate electrode of a transistor constituting a CMOS image sensor and a device isolation film can be minimized.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a CMOS image sensor includes a first conductive type semiconductor substrate having a plurality of transistors, an active region overlapping each gate electrode of the transistors, a device isolation film adjacent to the active region, and a first conductive type heavily doped impurity ion region formed between the active region and the device isolation film.

In another aspect, a method for fabricating a CMOS image sensor includes forming a device isolation film that defines an active region on a first conductive type semiconductor substrate, forming a first photoresist pattern that exposes a predetermined portion of the device isolation film and a predetermined portion of the active region, and forming a first conductive type heavily doped impurity ion region in the exposed substrate by implanting first conductive type heavily doped impurity ions into the entire surface of the substrate.

Preferably, after forming the first conductive type heavily doped impurity ions, the method further includes sequentially forming a gate insulating film and a gate electrode on the active region and the device isolation film, and forming a second photoresist pattern so as not to expose a portion where the device isolation film and the first conductive type heavily doped impurity ion region are formed.

Preferably, the first conductive type heavily doped impurity ion region has a width between 200 Å and 400 Å.

Preferably, the first conductive type heavily doped impurity ion region is formed by ion implantation at the concentration of 1E12 to 1E15 ions/cm².

Preferably, the first conductive type impurity ions are either B ions or BF₂ ions.

Preferably, the device isolation film exposed by the first photoresist pattern has a width between 50 Å and 2500 Å.

Preferably, the region exposed by the second photoresist pattern is a region into which second conductive type impurity ions are implanted to form one of a diffusion region for an LDD structure, source and drain regions, and a floating diffusion region.

In the active region overlapping the gate electrodes constituting the CMOS image sensor according to the present invention, the first conductive type heavily doped impurity ion region is formed at the boundary between the active region below each gate electrode and the device isolation film adjacent to the active region. In this case, it is possible to solve a problem such as electron carrier caused at the boundary the device isolation film and the active region due to the second conductive type impurity ion implantation.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a circuit diagram illustrating a unit pixel structure of a related art CMOS image sensor;

FIG. 2 is a layout illustrating a unit pixel of a related art CMOS image sensor;

FIG. 3A to FIG. 3C are sectional views illustrating the process steps of fabricating a related art CMOS image sensor, taken along line A-A′ of FIG. 2;

FIG. 4 is a sectional view illustrating a structure of a related art CMOS image sensor, taken along line B-B′ of FIG. 2;

FIG. 5 is a layout illustrating a unit pixel of a CMOS image sensor according to the present invention;

FIG. 6 is a structural sectional view taken along line C-C′ of FIG. 5; and

FIG. 7A to FIG. 7C are sectional views illustrating the process steps of fabricating a CMOS image sensor according to the present invention.

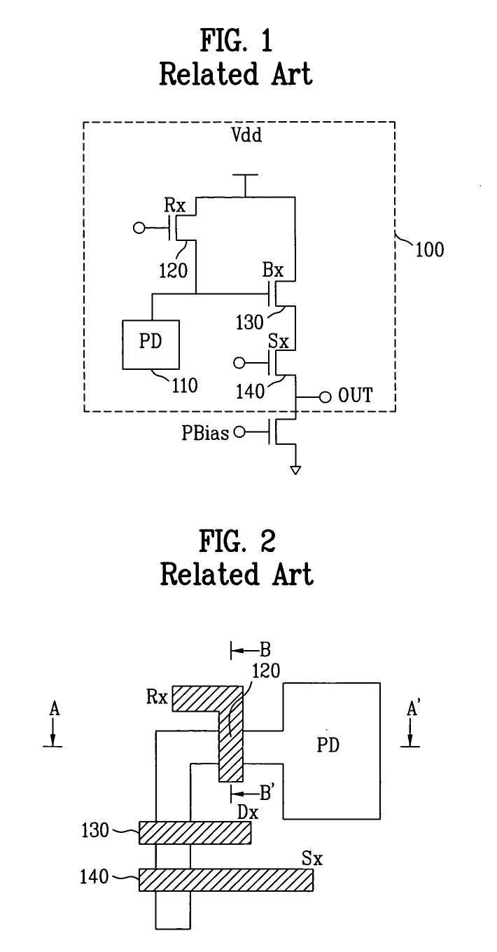

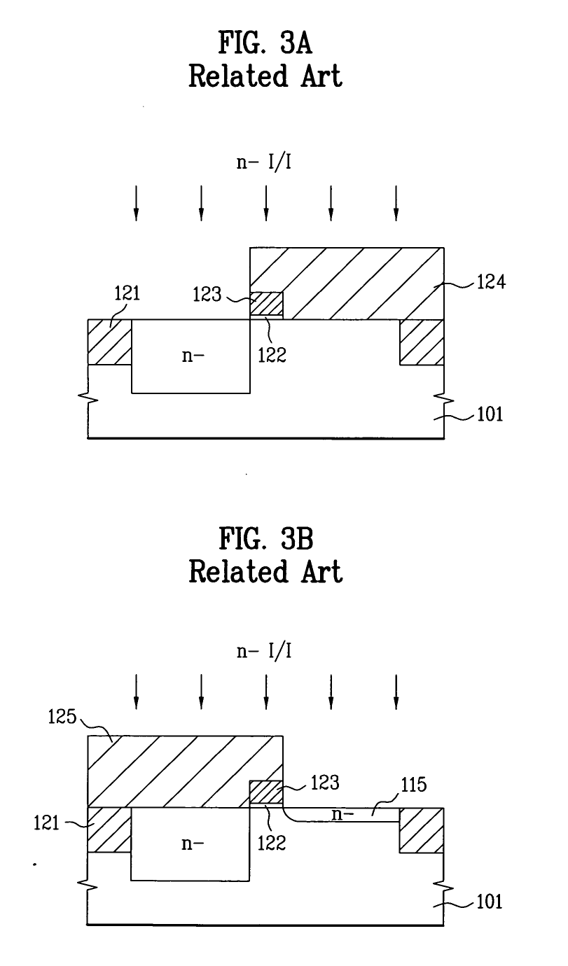

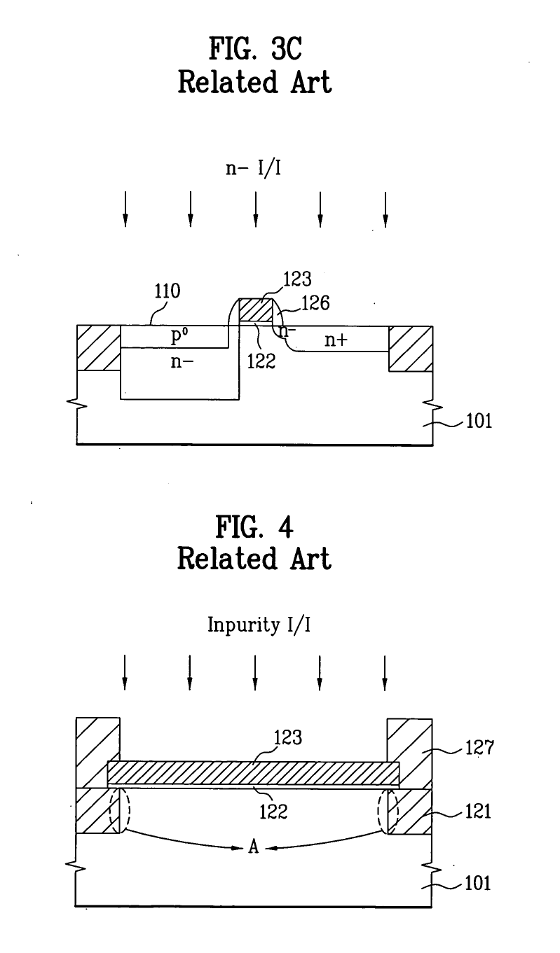

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a CMOS image sensor according to the present invention and a method for fabricating the same will be described as follows.

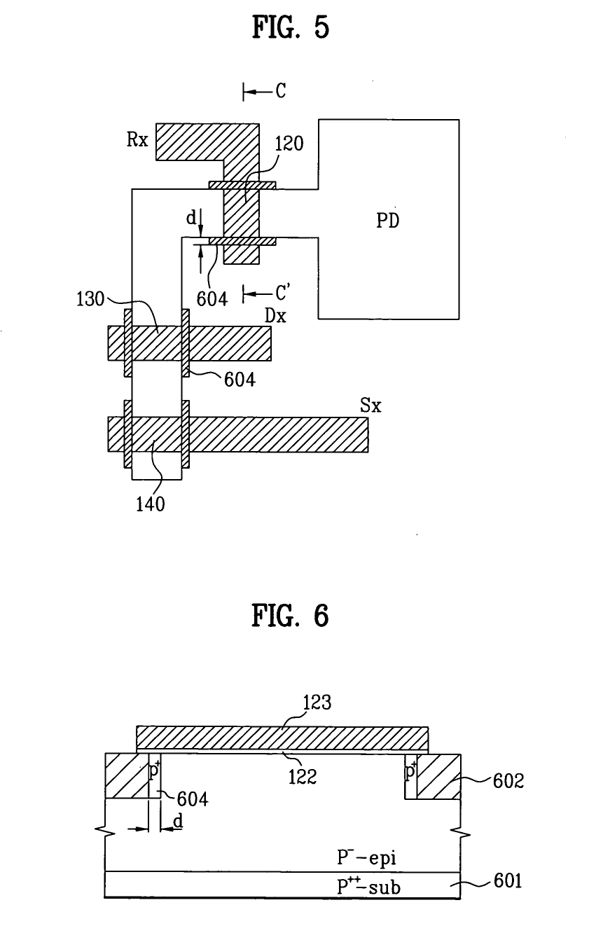

FIG. 5 is a layout illustrating a unit pixel of a CMOS image sensor according to the present invention. As shown in FIG. 5, an active region is defined on a first conductive type semiconductor substrate of a unit pixel by a field region. The active region corresponds to a region inside a solid line in FIG. 5. The field region denotes a region where a device isolation film (not shown) is formed and corresponds to a region outside the active region. A gate electrode of a reset transistor Rx 120, a gate electrode of a driver transistor Dx 130, and a gate electrode of a select transistor Sx 140 are arranged to overlap a predetermined portion of the active region. A photodiode surrounded by the device isolation film is formed at one side of the active region.

In the active region that overlaps the gate electrodes, a first conductive type heavily doped impurity ion region P⁺ 604 is formed at the boundary between the active region below each gate electrode and the device isolation film adjacent to the active region.

The active region overlapping the gate electrodes and adjacent to the gate electrodes corresponds to a second conductive type impurity ion implantation region for forming a diffusion region for an LDD structure, source and drain regions, or a floating diffusion region by means of the process steps of fabricating a typical CMOS image sensor.

The sectional structure of the CMOS image sensor, taken along line C-C′ of FIG. 5, will be described with reference to FIG. 6. The line C-C′ of FIG. 5 denotes the section of a portion where the gate electrode of the reset transistor is formed. It is noted that the gate electrode of the drive transistor and the gate electrode of the select transistor have the same sectional structure as that of the gate electrode of the reset transistor.

As shown in FIG. 6, a P⁻ type epitaxial layer P⁻-epi is formed on a first conductive type semiconductor substrate 601, for example, P⁺⁺ type monosilicon substrate. A device isolation film 602 is formed in a field region of the semiconductor substrate 601 to define an active region of the semiconductor substrate 601. The device isolation film 602 is formed by a STI process or a local oxidation of silicon (LOCOS) process. A first conductive type heavily doped impurity ion region P⁺ 604 is formed at the boundary between the device isolation film 602 and the active region. The first conductive type heavily doped impurity ion region P⁺ 604 has a width between 200 Å and 400 Å.

Meanwhile, as described above, the active region defined by the device isolation film 602 corresponds to a second conductive type impurity ion implantation region for forming a diffusion region for an LDD structure, source and drain regions, or a floating diffusion region. The first conductive type heavily doped impurity ion region 604 captures electron carrier caused by a defect generated by ion implantation at the boundary between the device isolation film 602 and the active region and provides a recombination area between the electron carrier and hole carrier existing in the first conductive type heavily doped impurity ion region.

A method for fabricating the aforementioned CMOS image sensor according to the present invention will be described in more detail.

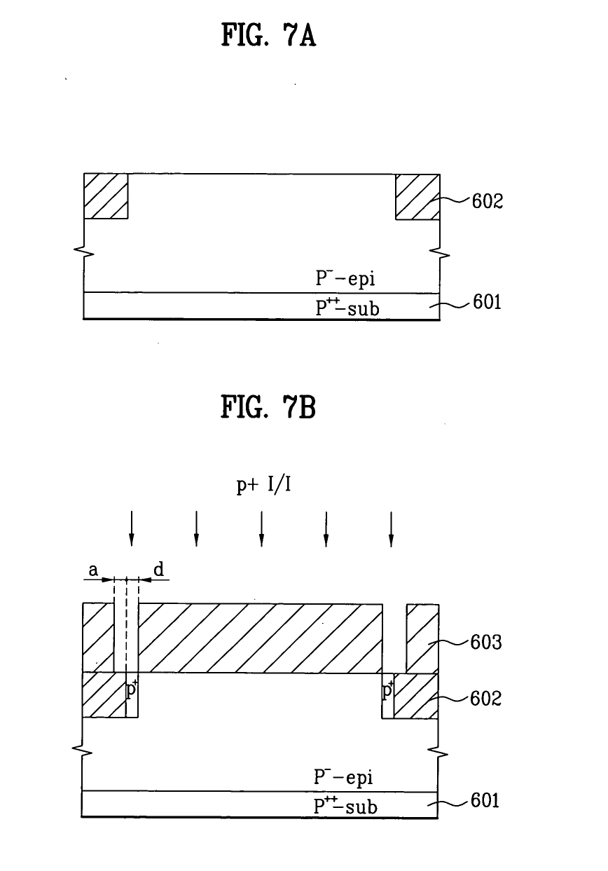

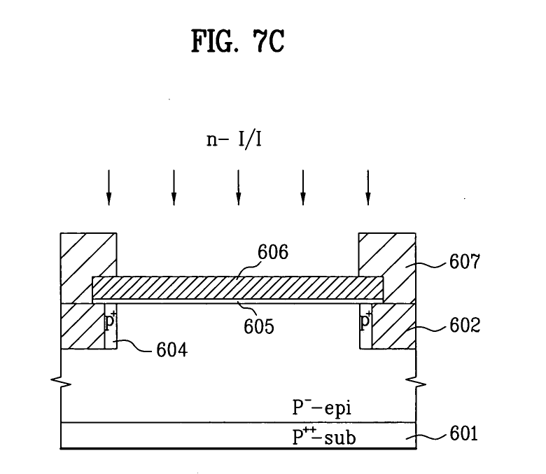

As shown in FIG. 7A, a semiconductor substrate 601, for example P type monosilicon substrate P⁺⁺-sub 601 is prepared. A P⁻ type epitaxial layer P⁻-epi may previously be formed in the semiconductor substrate 601. The P⁻ type epitaxial layer deeply forms a depletion region in a photodiode so as to increase capability of a low voltage photodiode that collects optical charges and to improve optical sensitivity.

Subsequently, the device isolation film 602 is formed in the field region of the semiconductor substrate 601 by the STI process or the LOCOS process to define the active region of the semiconductor substrate 601. The device isolation film 602 may be formed by a poly buffer LOCOS (PBL) process or a recessed LOCOS (R-LOCOS) process.

In a state that the device isolation film 602 is formed, as shown in FIG. 7B, a photoresist film is deposited on the entire surface of the substrate 601. The photoresist film is selectively patterned by a photolithography process to form a photoresist pattern 603. The active region and the device isolation film 602 are partially exposed by the photoresist pattern 603. That is, a predetermined portion where the active region adjoins the device isolation film 602 is exposed by the photoresist pattern 603. The width of the active region exposed by the photoresist pattern 603 is 200 Å to 400 Å while the width of the device isolation film 602 exposed by the photoresist film 603 is 50 Å to 2500 Å. These dimensions are defined considering a light source used during an exposure process of the typical photolithography process.

In more detail, the photolithography process for formation of the photoresist pattern includes deposition, exposure, development and separation. The exposure process serves as a main factor for a fine profile of the photoresist film. The exposure process is to irradiate lights onto a predetermined portion of the photoresist film using UV lights or DUV lights as a light source. Recently, with high packing density of a semiconductor device, the wavelength of the light source decreases gradually. At present, I-line widely used as a light source has a wavelength of 365 nm.

In case that the photoresist film is patterned using the I-line as a light source, deviation of about 0.15 μm occurs between the originally set profile and the formed photoresist pattern due to some factors such as the width of the wavelength.

Referring to this technical basis, the widths of the active region and the device isolation film 602 exposed by the photoresist pattern are set considering the exposure deviation in the I-line.

In a state that the photoresist pattern is formed, the first conductive type heavily doped impurity ions are implanted into the entire surface of the substrate 601. At this time, B ions or BF₂ ions may be used as the first conductive type impurity ions, and the impurity ions are preferably implanted at the concentration of IE12 to IE15 ions/cm². The first conductive type heavily doped impurity ion region is formed by ion implantation in the substrate 601 of the active region adjoining the device isolation film 602.

Meanwhile, the first conductive type impurity ions are preferably implanted before the second conductive type impurity ions are implanted to form a diffusion region for an LDD structure, source and drain region, or a floating diffusion region in the active region.

In a state that the first conductive type impurity ion region is formed, as shown in FIG. 7C, a gate insulating film 605 and a gate electrode 606 are sequentially formed on the active region and the device isolation film 602. In this state, the second conductive type impurity ions are implanted into the entire surface of the substrate 601. At this time, the device isolation film 602 or both the device isolation film 602 and the first conductive type impurity ion region are masked by an ion implantation mask such as a photoresist pattern 607.

The diffusion region for an LDD structure, the source and drain regions, or the floating diffusion region is formed in the active region by the first conductive type impurity ion implantation. In this case, since the first conductive type impurity ion region is previously formed at the boundary between the active region and the device isolation film 602, the first conductive type impurity ion region provides hole carrier to cause electron-hole recombination. Therefore, it is possible to solve a problem such as electron carrier caused by a defect between the device isolation film 602 and the active region during the second conductive type impurity ion implantation.

While the method for fabricating a CMOS image sensor according to the present invention has been described based on the section taken along line C-C′ of FIG. 5, it equally apples to the sectional structure of the gate electrodes of all the transistors constituting a CMOS image sensor.

Furthermore, in the embodiment of the present invention, while the CMOS image sensor based on three transistors has been described, other CMOS image sensors may be realized in avoiding substrate damage due to ion implantation at the boundary between the active region and the device isolation film.

As aforementioned, the CMOS image sensor and the method for fabricating the same have the following advantages.

In the active region overlapping the gate electrodes constituting the CMOS image sensor, the first conductive type heavily doped impurity ion region is formed at the boundary between the active region below each gate electrode and the device isolation film adjacent to the active region. In this case, it is possible to solve a problem such as electron carrier caused at the boundary the device isolation film and the active region due to the second conductive type impurity ion implantation.

It will be apparent to those skilled in the art that various modifications and variations can be made in the present invention. Thus, it is intended that the present invention covers the modifications and variations of this invention provided they come within the scope of the appended claims and their equivalents.

1. A CMOS image sensor comprising:
a first conductive type semiconductor substrate having a plurality of transistors;
an active region overlapping each gate electrode of the transistors;
a device isolation film adjacent to the active region; and
a first conductive type heavily doped impurity ion region formed between the active region and the device isolation film.

2. The CMOS image sensor of claim 1, wherein the first conductive type heavily doped impurity ion region has a width between 200 Å and 400 Å.

3. The CMOS image sensor of claim 1, wherein the active region corresponds to a region into which second conductive type impurity ions are implanted to form one of a diffusion region for an LDD structure, source and drain regions, and a floating diffusion region.

3. A method for fabricating a CMOS image sensor comprising:
forming a device isolation film that defines an active region on a first conductive type semiconductor substrate;
forming a first photoresist pattern that exposes a predetermined portion of the device isolation film and a predetermined portion of the active region; and
forming a first conductive type heavily doped impurity ion region in the exposed substrate by implanting first conductive type heavily doped impurity ions into the entire surface of the substrate.

5. The method of claim 4, after forming the first conductive type heavily doped impurity ions, further comprising:
sequentially forming a gate insulating film and a gate electrode on the active region and the device isolation film; and
forming a second photoresist pattern so as not to expose a portion where the device isolation film and the first conductive type heavily doped impurity ion region are formed.

6. The method of claim 4, wherein the first conductive type heavily doped impurity ion region has a width between 200 Å and 400 Å.

7. The method of claim 4, wherein the first conductive type heavily doped impurity ion region is formed by ion implantation at the concentration of 1E12 to 1E15 ions/cm².

8. The method of claim 4, wherein the first conductive type impurity ions are either B ions or BF₂ ions.

9. The method of claim 4, wherein the device isolation film exposed by the first photoresist pattern has a width between 50 Å and 2500 Å.

10. The method of claim 5, wherein the region exposed by the second photoresist pattern is a region into which second conductive type impurity ions are implanted to form one of a diffusion region for an LDD structure, source and drain regions, and a floating diffusion region.
